(19) United States
(12) Patent Application Publication
(10) Pub. No.: US 2012/0084548 A1
(43) Pub. Date: Apr. 5, 2012

(54) Method and Module for Simulating Keyboard

(75) Inventors: Tsai-Ming Cheng, Taipei City (TW); Chih-Lung Chen, Taipei City (TW); Shr-Da Mai, Taipei City (TW); Yu-Ting Wang, Taipei City (TW)

(73) Assignee: PEGATRON CORPORATION, Taipei (TW)

(21) Appl. No.: 13/239,618

(22) Filed: Sep. 22, 2011

(30) Foreign Application Priority Data
Sep. 28, 2010 (TW) 099132809

(51) Int. Cl. G06F 9/00; G06F 3/048; H03K 17/94

(52) U.S. Cl. 713/2; 341/26; 715/810

(57) ABSTRACT

This disclosure provides a method and a module for simulating a keyboard used in an electronic device having a hot key. The method for simulating a keyboard at least includes the following steps. First, whether the hot key is pressed is checked. If the hot key is pressed, a pressing time of the hot key is calculated. If the pressing time is over a first predetermined time, a first scanning code is sent. When the pressing time is within the first predetermined time, whether to send a second scanning code is determined according to the pressing time.

### CROSS-REFERENCE TO RELATED APPLICATIONS

This Non-provisional application claims priority under 35 U.S.C. §119(a) on Patent Application No(s). 099132809 filed in Taiwan, Republic of China on Sep. 28, 2010, the entire contents of which are hereby incorporated by reference.

### BACKGROUND OF THE INVENTION

1. Field of the Invention

This invention relates to a method for simulating a keyboard and, more particularly, to a method for simulating a keyboard used in an electronic device.

2. Description of the Related Art

A basic input/output system (BIOS) is a basic software code loaded by an electronic device, and therefore the BIOS can be regarded as a mini operating system specially communicating with hardware. Further, the BIOS also includes a diagnosis function thus to ensure that some important hardware elements such as a keyboard, a disk drive, an input/output port and so on can normally operate and can be correctly initialized. Accordingly, when the electronic device malfunctions, the BIOS is first checked.

FIG. 1 is a system block diagram showing an electronic device. In FIG. 1, the electronic device 100 includes a north bridge chip 110 and a south bridge chip 120 connected with each other, and the north bridge chip 110 is also connected with a central processing unit (CPU) 130 and a main memory 140. Further, the south bridge chip 120 has a complementary metal oxide semiconductor (CMOS) memory 122 connected with a flash ROM 150. The flash ROM 150 is used for storing the software code of the BIOS, and the CMOS memory 122 is used for storing setting values of the BIOS. The electronic device 100 also includes an embedded chip 160 connected with the south bridge chip 120, and the embedded chip 160 can allow a user to directly control the south bridge chip 120.

Generally speaking, after the electronic device 100 is powered on, the CPU 130 may first search the flash ROM 150 where the software code of the BIOS is stored and then determine whether the data in the CMOS memory 122 is correct. If the data is correct, the data stored in the CMOS memory 122 and the information of the found hardware are decompressed into the main memory 140, and the hardware test, i.e. power on self test (POST) is executed to allow the user to see the basic information of different hardware on the screen. Afterward the operating system of the electronic device 100 is entered.

For a conventional electronic device, when the operating system is not loaded yet, a universal serial bus (USB) interface or a PS/2 interface has to be used to connect a keyboard or a mouse for input thus to adjust the setting values in the BIOS such as boot device priority. However, the following cases may be inconvenient for the user.

For example, a remote controller may be used to control a conventional home theater personal computer (HTPC). If the HTPC malfunctions or crashes thus failing to enter the operating system, the remote controller relying on the operating system fails to be used certainly. Accordingly, to check the BIOS setting in the HTPC and eliminate malfunctions, the keyboard has to be connected to the HTPC.

Further, for convenient carry, a conventional portable media player such as an electronic book usually fails to have an independent inputting device such as a physical keyboard, and therefore it has to be connected with an external inputting device such as a keyboard or a mouse. If the electronic device fails to be shut down normally last time, the keyboard has to be connected to the malfunctioning electronic device to check or modify certain basic setting of the BIOS after the electronic device is rebooted. It is inconvenient for the user.

### BRIEF SUMMARY OF THE INVENTION

The invention provides a method and a module for simulating a keyboard, allowing a hot key of an electronic device to replace the keyboard to control the electronic device.

One embodiment of the invention provides a method for simulating a keyboard used in an electronic device having a hot key. The method for simulating a keyboard includes the following steps. Whether the hot key is pressed is checked. If the hot key is pressed, a pressing time of the hot key is calculated. When the pressing time is over a first predetermined time, a first scanning code is sent. When the pressing time is within the first predetermined time, whether to send a second scanning code is determined according to the pressing time.

In one embodiment, the electronic device may further have a keyboard, and the hot key may be independent of the keyboard.

In one embodiment, the first scanning code may correspond to a first key of the keyboard, and the second scanning code may correspond to a second key of the keyboard.

In one embodiment, the step of determining whether to send the second scanning code according to the pressing time when the pressing time is within the first predetermined time may include a step of sending the second scanning code when the pressing time is over a second predetermined time.

In one embodiment, the method may include a step of checking whether the hot key is released, and whether the pressing time is over the second predetermined time may be determined when the hot key is released.

In one embodiment, the method may further include a step of executing a booting procedure.

In one embodiment, before the step of checking whether the hot key is pressed, the method may further include a step of entering a menu of an error recovery mode having a plurality of options.

In one embodiment, the method may further include steps of executing a selected option in the options according to the first scanning code and switching between the options according to the second scanning code if the second scanning code is sent.

In one embodiment, the steps of executing the selected option in the options according to the first scanning code and switching between the options according to the second scanning code if the second scanning code is sent may be executed by an operating system of the electronic device.

In one embodiment, before the step of checking whether the hot key is pressed, the method may further include a step of entering a menu of setting a basic input/output system (BIOS) having a plurality of options.

In one embodiment, the method may further include steps of executing a selected option in the options according to the first scanning code and switching between the options according to the second scanning code if the second scanning code is sent.

In one embodiment, the steps of executing the selected option in the options according to the first scanning code and switching between the options according to the second scanning code if the second scanning code is sent may be executed by the BIOS of the electronic device.

One embodiment of the invention provides a module for simulating a keyboard used in an electronic device having a hot key, and the module is electrically connected with the hot key. The module includes a first unit for checking whether the hot key is pressed, a second unit for calculating a pressing time of the hot key if the hot key is pressed, a third unit for sending a first scanning code when the pressing time is over a first predetermined time, and a fourth unit for determining whether to send a second scanning code according to the pressing time when the pressing time is within the first predetermined time.

In one embodiment, the electronic device may further have a keyboard, and the hot key may be independent of the keyboard. The first scanning code sent by the third unit may correspond to a first key of the keyboard, and the second scanning code sent by the fourth unit may correspond to a second key of the keyboard.

In one embodiment, the module may be an embedded control chip.

In one embodiment, the electronic device where the module is used may further include a display unit for displaying a menu having a plurality of options.

In one embodiment, the electronic device where the module is used may further include a BIOS for executing a selected option in the options according to the first scanning code sent by the third unit or switching between the options according to the second scanning code sent by the fourth unit.

In one embodiment, the electronic device where the module is used may further include an operating system for executing a selected option in the options according to the first scanning code sent by the third unit or switching between the options according to the second scanning code sent by the fourth unit.

In the embodiment of the invention, after the electronic device is booted, the electronic device is operated via a hot key, and different scanning codes are sent to a control unit according to different pressing time of the hot key. Accordingly, even if the electronic device has no keyboard, no matter the electronic device enters the operating system or the menu of setting the BIOS, the electronic device can also be operated via the hot key replacing the keyboard.

These and other features, aspects, and advantages of the present invention will become better understood with regard to the following description, appended claims, and accompanying drawings.

### BRIEF DESCRIPTION OF THE DRAWINGS

FIG. 1 is a system block diagram showing an electronic device;

FIG. 2A and FIG. 2B are flow charts showing a method for simulating a keyboard used in an electronic device according to one embodiment of the invention, respectively; and

FIGS. 3A to 3C are schematic diagrams showing an electronic device in a menu of an error recovery mode according to one embodiment of the invention, respectively.

FIG. 4 is a block diagram showing an embedded chip connected with a hot key.

### DETAILED DESCRIPTION OF THE INVENTION

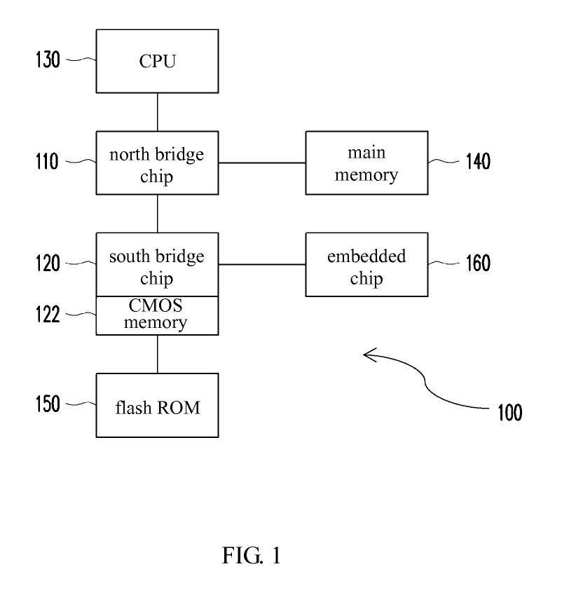

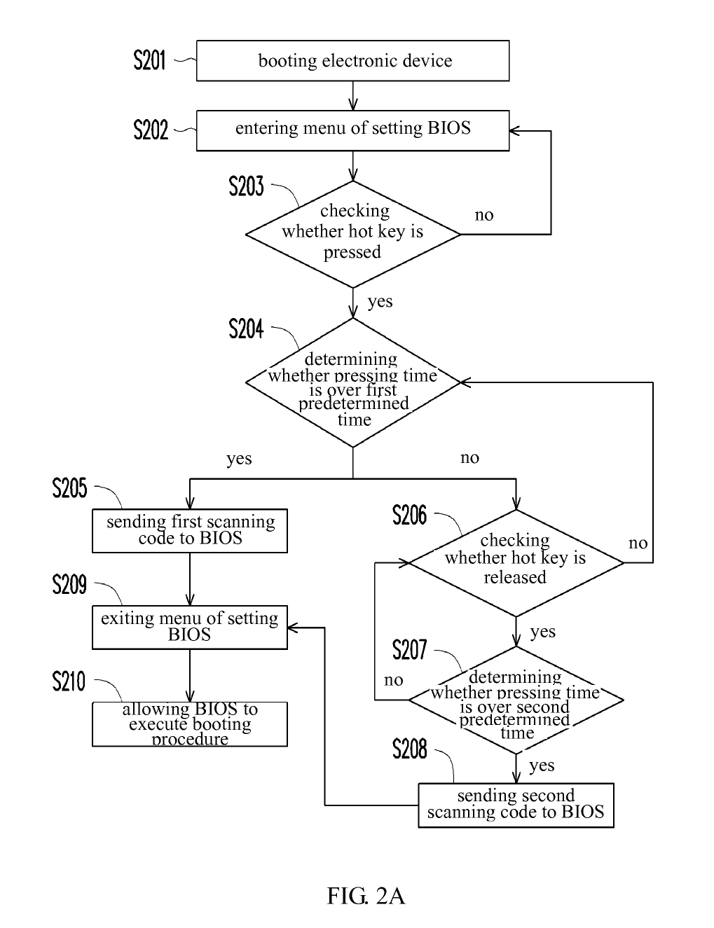

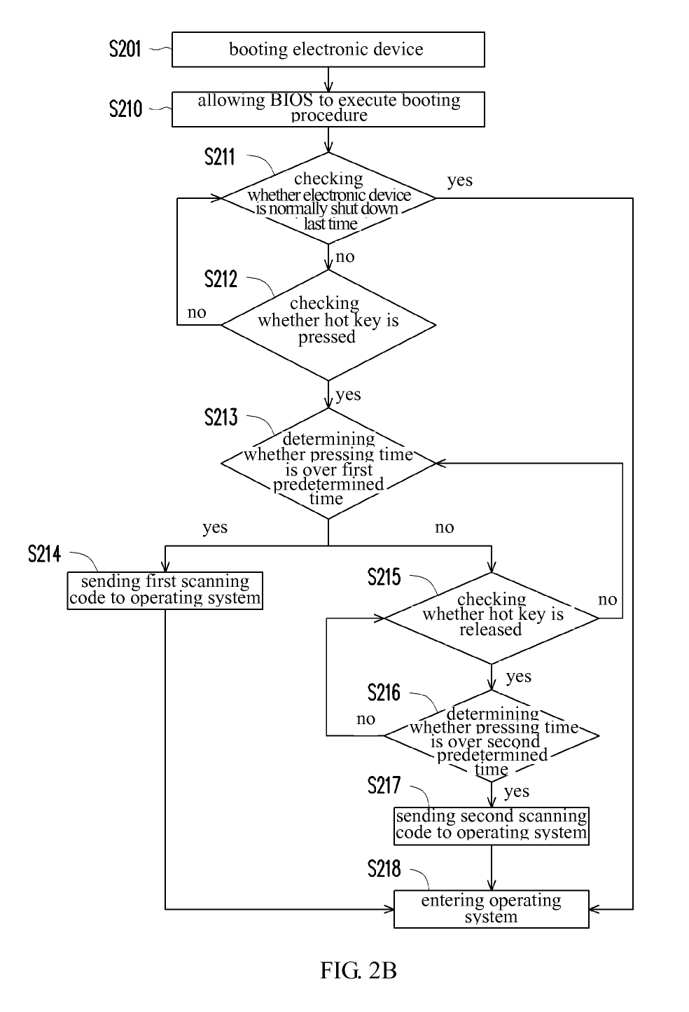

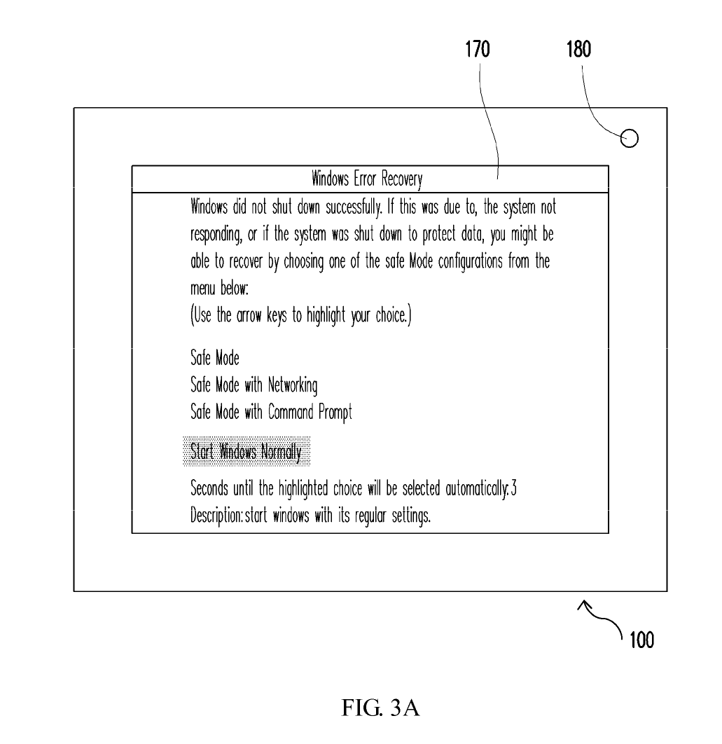

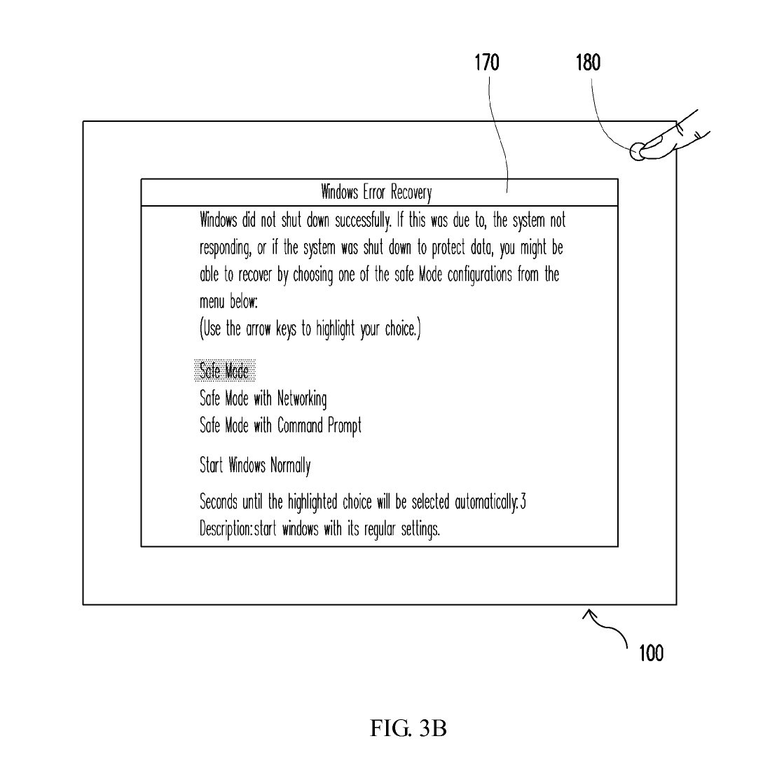

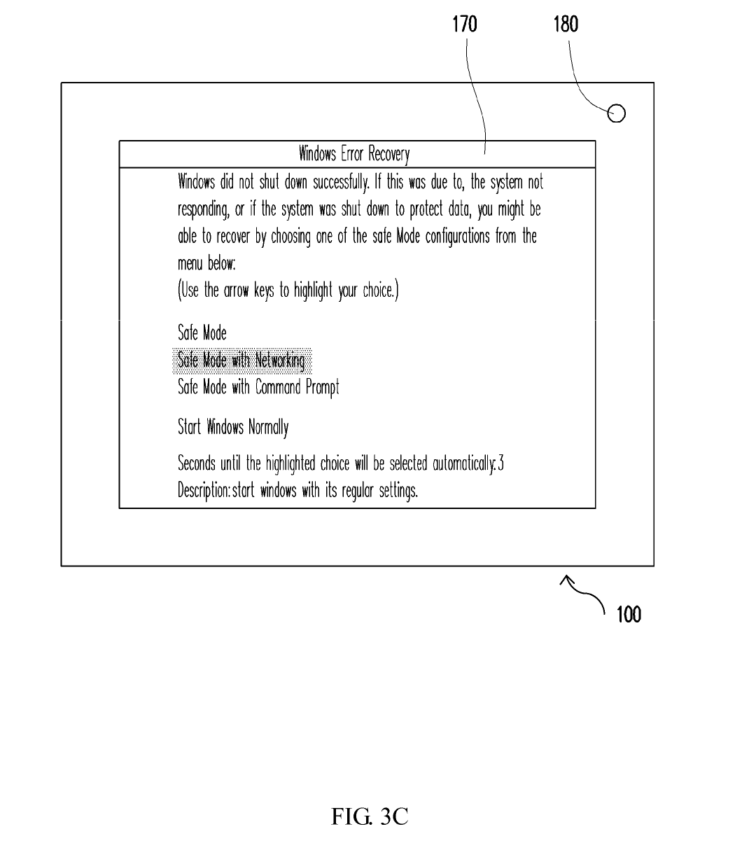

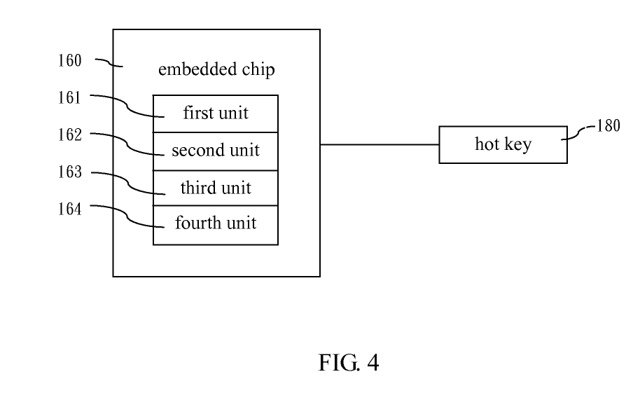

FIG. 2A and FIG. 2B are flow charts showing a method for simulating a keyboard used in an electronic device according to one embodiment of the invention, respectively. FIGS. 3A to 3C are schematic diagrams showing an electronic device in a menu of an error recovery mode according to one embodiment of the invention, respectively. FIG. 4 is a block diagram showing an embedded chip connected with a hot key. Please refer to FIG. 2A, FIG. 2B, and FIGS. 3A through 3C. The system structure of the electronic device 100 is the same as that in FIG. 1, and therefore it is not described for concise purpose. The electronic device 100 may be a tablet computer having a screen 170 and a hot key 180 beside the screen 170. The hot key 180 is a physical button electrically connected with an embedded chip 160. Further, in the embodiment, the electronic device 100 can include a keyboard (not shown) which may be a virtual keyboard displayed by the screen 170 (here it may be a touch screen) or an external keyboard. The invention is not limited thereto. In addition, the hot key 180 is independent of the keyboard.

Please refer to FIG. 2A first. After the electronic device 100 is booted in step S201, the electronic device 100 enters a menu of setting a basic input/output system (BIOS) via pressing the keyboard (such as the DEL key) by a user in step S202. Then the embedded chip 160 checks whether the hot key is pressed in step S203 and determines whether a pressing time is over a first predetermined time in step S204.

When the pressing time is over the first predetermined time, the embedded chip 160 sends a first scanning code to the BIOS in step S205. When the pressing time is within the first predetermined time, the embedded chip 160 further checks whether the hot key 180 is released in step S206. If the hot key 180 is not released, the embedded chip 160 may return to step S204 to determine whether the pressing time of the hot key 180 is over the first predetermined time. If the pressing time is over the first predetermined time, the embedded chip 160 may further determine whether the pressing time of the hot key 180 is over a second predetermined time in step S207. If the pressing time of the hot key 180 is over the second predetermined time, in step S208, the embedded chip 160 sends a second scanning code to the BIOS.

In other words, in the flow chart according to the embodiment, the functions of the first scanning code and the second scanning code equate part function of the keyboard. For example, the function of the second scanning code equates that of the down or up direction key of the keyboard, while the function of the first scanning code equates that of the ENTER key of the keyboard. That is, in the embodiment, different keys of the keyboard are simulated via pressing a single hot key 180 and controlling the pressing time thereof thus to operate the electronic device 100.

Further, after the scanning codes in step S205 or step S208 are sent, the electronic device 100 which has finished the setting of the menu exits the menu of setting the BIOS and allows the BIOS to execute a booting procedure in step S209 and step S210.

FIGS. 3A to 3C are schematic diagrams showing an electronic device in a menu of an error recovery mode according to one embodiment of the invention, respectively. Please refer to FIG. 2B and FIGS. 3A through 3C. How the electronic device 100 is operated via the hot key 180 in another state is described hereinbelow. Differently, in step S201 and step S210, the BIOS may execute the booting procedure after the electronic device is booted, and in step S211, whether the electronic device is normally shut down last time may be checked. If the electronic device 100 is not normally shut down last time, in FIG. 3A, the operating system may enter a menu of an error recovery mode after the electronic device 100 is booted, allowing the user to start the operating system in a corresponding method to repair errors generated due to abnormal shutdown last time.

In the embodiment, steps S212 to S214 are similar to steps S203 through S205 in FIG. 2A and steps S215 through S217 are similar to steps S206 through S208 in FIG. 2A, and therefore they are not described for concise purpose. The difference only lies in the fact that, the flow chart shown in FIG. 2A is executed in the menu of setting the BIOS, while the flow chart shown in FIG. 2B is executed in the operating system. That is, the first scanning code and the second scanning code generated in the former are sent to the BIOS to allow the corresponding actions to be executed, while the first scanning code and the second scanning code generated in the latter are sent to the operating system to allow the corresponding actions to be executed.

For example, in FIGS. 3A and 3B, after the electronic device 100 enters the menu of an error recovery mode, the embedded chip 160 sends the second scanning code to the operating system via a short press of the hot key 180 by the user (in FIG. 3B), thus changing highlighting areas on the screen 170 to select different options (in FIG. 3C). After the option is selected, the embedded chip 160 can send the first scanning code to the operating system via a long press of the hot key 180 by the user (in FIG. 3B), thus executing the selected option.

In a word, no matter the electronic device 100 enters the menu of setting the BIOS or the menu of an error recovery mode of the operating system, the electronic device can always be operated via pressing the hot key 180 by the user.

Refer to FIG. 4, the embedded chip 160 is electrically connected with the hot key 180. The embedded chip 160 includes a first unit 161 for checking whether the hot key is pressed, a second unit 162 for calculating a pressing time of the hot key if the hot key is pressed, a third unit 163 for sending a first scanning code when the pressing time is over a first predetermined time, and a fourth unit 164 for determining whether to send a second scanning code according to the pressing time when the pressing time is within the first predetermined time.

To sum up, in the electronic device according to the embodiment of the invention, different keys of the physical keyboard can be simulated via pressing the hot key and the pressing time thereof, and therefore the physical keyboard may not be needed to operate the electronic device.

Further, no matter the electronic device enters the menu of setting the BIOS or the menu of an error recovery mode of the operating system after the electronic device is booted, the hot key can always be operated. Especially, when the electronic device without the physical keyboard is rebooted after shut down abnormally last time, the hot key can replace the keyboard to conveniently control the electronic device via the method for simulating a keyboard according to the embodiment of the invention.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for simulating a keyboard used in an electronic device having a hot key, the method comprising at least the following steps of:
checking whether the hot key is pressed;
calculating a pressing time of the hot key if the hot key is pressed;
sending a first scanning code when the pressing time is over a first predetermined time; and
determining whether to send a second scanning code according to the pressing time when the pressing time is within the first predetermined time.

2. The method according to claim 1, wherein the electronic device further has a keyboard, and the hot key may be independent of the keyboard.

3. The method according to claim 2, wherein the first scanning code corresponds to a first key of the keyboard, and the second scanning code corresponds to a second key of the keyboard.

4. The method according to claim 1, wherein the step of determining whether to send the second scanning code according to the pressing time when the pressing time is within the first predetermined time comprises a step of:
sending the second scanning code when the pressing time is over a second predetermined time.

5. The method according to claim 4, further comprising a step of:
checking whether the hot key is released,
wherein whether the pressing time is over the second predetermined time is determined when the hot key is released.

6. The method according to claim 1, further comprising a step of:
executing a booting procedure.

7. The method according to claim 1, before the step of checking whether the hot key is pressed, further comprising a step of:
entering a menu of an error recovery mode having a plurality of options.

8. The method according to claim 7, further comprising steps of:
executing a selected option in the options according to the first scanning code; and
switching between the options according to the second scanning code if the second scanning code is sent.

9. The method according to claim 8, wherein the steps of executing the selected option in the options according to the first scanning code and switching between the options according to the second scanning code if the second scanning code is sent are executed by an operating system of the electronic device.

10. The method according to claim 1, before the step of checking whether the hot key is pressed, further comprising a step of:
entering a menu of setting a basic input/output system (BIOS) having a plurality of options.

11. The method according to claim 10, further comprising steps of:
executing a selected option in the options according to the first scanning code; and
switching between the options according to the second scanning code if the second scanning code is sent.

12. The method according to claim 11, wherein the steps of executing the selected option in the options according to the first scanning code and switching between the options according to the second scanning code if the second scanning code is sent are executed by the BIOS of the electronic device.

13. A module for simulating a keyboard used in an electronic device having a hot key, the module electrically connected with the hot key, the module at least comprising:
a first unit for checking whether the hot key is pressed;
a second unit for calculating a pressing time of the hot key if the hot key is pressed;
a third unit for sending a first scanning code when the pressing time is over a first predetermined time; and
a fourth unit for determining whether to send a second scanning code according to the pressing time when the pressing time is within the first predetermined time.

14. The module according to claim 13, wherein the electronic device further has a keyboard, the hot key is independent of the keyboard, the first scanning code sent by the third unit corresponds to a first key of the keyboard, and the second scanning code sent by the fourth unit corresponds to a second key of the keyboard.

15. The module according to claim 13, wherein the module is an embedded control chip .

16. The module according to claim 13, wherein the electronic device where the module is used further comprises a display unit for displaying a menu having a plurality of options.

17. The module according to claim 16, wherein the electronic device where the module is used further comprises a BIOS for executing a selected option in the options according to the first scanning code sent by the third unit or switching between the options according to the second scanning code sent by the fourth unit.

18. The module according to claim 16, wherein the electronic device where the module is used further comprises an operating system for executing a selected option in the options according to the first scanning code sent by the third unit or switching between the options according to the second scanning code sent by the fourth unit.
